(19) United States
(12) Patent Application Publication
(10) Pub. No.: US 2015/0311345 A1
(43) Pub. Date: Oct. 29, 2015

(54) THIN FILM TRANSISTOR AND METHOD OF FABRICATING THE SAME, DISPLAY SUBSTRATE AND DISPLAY DEVICE

(71) Applicant: BOE TECHNOLOGY GROUP CO., LTD., Beijing (CN)

(72) Inventor: Ce Zhao, Beijing (CN)

(21) Appl. No.: 14/443,554

(22) PCT Filed: Sep. 19, 2014
(86) PCT No.: PCT/CN2014/086920

§ 371 Date: May 18, 2015

(30) Foreign Application Priority Data
Apr. 28, 2014 (CN) 201410174409.5

(51) Int. Cl. H01L 29/786; H01L 29/66; H01L 27/12; H01L 21/441; H01L 21/477; H01L 29/24; H01L 21/02

(52) U.S. Cl. CPC H01L 29/7869; H01L 29/24; H01L 29/66969; H01L 21/02565; H01L 21/441; H01L 21/477; H01L 29/78606; H01L 29/78696; H01L 27/1225

(57) ABSTRACT

The present invention provides a thin film transistor, a fabricating method thereof, a display substrate and a display device. In the fabricating method, a protective layer and an oxide active layer are patterned by one patterning process, to form patterns of the protective layer and the oxide active layer; and annealing is performed in an oxygen-containing atmosphere, so that the material of the oxide active layer diffuses into the protective layer through a contact surface between the oxide active layer and the protective layer, to form a transitional region in the protective layer, and the material of the protective layer diffuses into the oxide active layer through the contact surface, to form a transitional region in the oxide active layer, the transitional regions are configured to reduce an off-state current of the thin film transistor.

### FIELD OF THE INVENTION

The present invention relates to the field of display technology, and particularly relates to a thin film transistor and a method of fabricating the same, a display substrate and a display device.

### BACKGROUND OF THE INVENTION

In recent years, with continuous development of flat panel display technology, large-size high-definition 3D liquid crystal displays and organic electroluminescent display (OLED) technology have become major trends of development. It has become difficult for traditional amorphous silicon thin film transistors to meet relevant technical requirements, and a thin film transistor with an active layer formed of an oxide (such as indium gallium zinc oxide (IGZO, In—Ga—Zn—O)) as the most promising thin film transistor for use in the next generation of flat panel displays almost satisfies all the technical requirements described above. FIG. 1 shows a structural diagram of an oxide (such as indium gallium zinc oxide (IGZO)) thin film transistor including a base substrate 1, a gate 2 disposed on the base substrate 1, a gate insulating layer 3 disposed on the gate 2, an indium gallium zinc oxide (IGZO) active layer 4 disposed on the gate insulating layer 3, an etch stop layer 5 disposed on the active layer 4 to protect the active layer 4 and prevent etchant from corroding an active region of the active layer 4, and source and drain electrodes 6 disposed on the etch stop layer 5.

When indium gallium zinc oxide (IGZO) is used as the material of the active layer of the thin film transistor, a bottom gate structure as shown in FIG. 1 is often adopted, and the etch stop layer 5 made of insulating material is used to protect the indium gallium zinc oxide (IGZO) active region from corrosion by the etchant for the source and drain electrodes 6. As the etch stop layer 5 is fabricated by use of the insulating material, via holes are required to be formed between the active layer 4 and the source and drain electrodes 6, and the active layer 4 is electrically connected with the source and drain electrodes 6 through the via holes. However, the fabricating process adds a step of patterning process for individually forming the etch stop layer 5, resulting in a complicated manufacturing procedure, a prolonged manufacturing period, a decreased yield and an increased production cost of the indium gallium zinc oxide (IGZO) thin film transistor.

### SUMMARY OF THE INVENTION

An object of the present invention is to provide a thin film transistor, a fabricating method thereof, a display substrate and a display device having a simple manufacturing procedure, a short manufacturing period, a high yield and a low production cost, in order to solve the problems of the complicated manufacturing procedure, the prolonged manufacturing period, the decreased yield and the high production cost of the thin film transistor, the fabricating method thereof, the display substrate and the display device in the prior art due to the separate patterning process needed for the etch stop layer.

The present invention provides a method of fabricating a thin film transistor, comprising steps of: forming an oxide active layer film and a protective layer film on a substrate, and patterning the oxide active layer film and the protective layer film by one patterning process, to form patterns of an oxide active layer and a protective layer, the protective layer film being made of a tin oxide-based material; forming a source and drain electrode film on the protective layer, and patterning the source and drain electrode film by a patterning process, to form patterns of source and drain electrodes; and annealing in an oxygen-containing atmosphere, so that the material of the oxide active layer diffuses into the protective layer through a contact surface between the oxide active layer and the protective layer, to form a transitional region in the protective layer, and the material of the protective layer diffuses into the oxide active layer through the contact surface, to form a transitional region in the oxide active layer, the transitional regions being configured to reduce an off-state current of the thin film transistor.

The protective layer further includes a non-transitional region away from the oxide active layer, and the non-transitional region is made of the tin oxide-based material.

Alternatively, the protective layer is formed of the transitional region.

The tin oxide-based material may be any of indium tin zinc oxide, aluminum tin zinc oxide, zinc tin oxide, gallium tin oxide, indium gallium tin oxide and indium tin oxide.

The oxide active layer may be made of indium gallium zinc oxide.

The transitional region may include indium gallium tin zinc oxide material.

In the step of annealing in the oxygen-containing atmosphere, the oxygen-containing atmosphere is a 1%-99% oxygen partial pressure atmosphere or a pure oxygen atmosphere.

In the step of annealing in the oxygen-containing atmosphere, the annealing is carried out at an annealing temperature within the range of 100° C. to 900° C.

The protective layer is formed by deposition in an oxygen-containing atmosphere, the oxygen-containing atmosphere is a 1%-99% oxygen partial pressure atmosphere or a pure oxygen atmosphere.

The present invention also provides a thin film transistor including an oxide active layer, a protective layer provided on the oxide active layer and source and drain electrodes, the protective layer includes a tin oxide-based material, a part of the oxide active layer in contact with the protective layer includes a transitional region, and a part of the protective layer in contact with the oxide active layer includes a transitional region, the transitional regions are configured to reduce an off-state current of the thin film transistor.

The protective layer further includes a non-transitional region away from the oxide active layer, and the transitional region contains material formed by mutual combination of the tin oxide-based material and the material of the oxide active layer, and the non-transitional region is made of the tin oxide-based material.

Alternatively, the protective layer is formed of the transitional region, and the transitional region contains material formed by mutual combination of the tin oxide-based material and the material of the oxide active layer.

One side of the protective layer is in contact with the oxide active layer, the other side of the protective layer is in contact with the source and drain electrodes, and the oxide active layer is electrically connected with the source and drain electrodes through the protective layer, respectively.

The tin oxide-based material may be any of indium tin zinc oxide, aluminum tin zinc oxide, zinc tin oxide, gallium tin oxide, indium gallium tin oxide and indium tin oxide.

The oxide active layer may be made of indium gallium zinc oxide.

The thickness of the protective layer may range from 1 nm to 100 nm.

The thickness of the oxide active layer may range from 5 nm to 200 nm.

The transitional region formed by mutual combination of the tin oxide-based material and the material of the oxide active layer includes indium gallium tin zinc oxide material.

The present invention also provides a display substrate including the thin film transistor described above.

The present invention also provides a display device including the display substrate described above.

In the thin film transistor, the display substrate and the display device of the present invention, as the protective layer is made of the tin oxide-based material that is insensitive to etching solution for conventional source and drain electrodes, the tin oxide-based protective layer provided on the oxide active layer can protect the oxide active layer from influence by the etching solution for the source and drain electrodes in fabrication of the source and drain electrodes. In addition, compared with the insulating etch stop layer adopted in the prior art, the tin oxide-based protective layer is made of semiconductor material and is electrically matched with the oxide active layer and the source and drain electrodes very well, so there is no need of fabricating via holes in implementation of electric connection between the source and drain electrodes and the oxide active layer. Moreover, the protective layer and the oxide active layer may be formed by one patterning process, and compared with the prior art, the photolithography procedure for individually forming the etch stop layer is omitted, and one patterning process is reduced, so that the product has a simple manufacturing procedure, a short manufacturing period, a high yield and a low production cost. In addition, annealing in the oxygen-containing atmosphere can repair damage of the active layer caused by plasma in deposition of the source and drain electrode film, and meanwhile, the transitional regions formed in respective parts of the oxide active layer and protective layer in contact with each other can reduce the off-state current of the thin film transistor.

### BRIEF DESCRIPTION OF THE DRAWINGS

FIG. 1 is a structural diagram of an oxide thin film transistor in the prior art.

FIG. 2 is a structural diagram after formation of a gate in a fabricating method of an oxide thin film transistor of a first embodiment of the present invention.

FIG. 3 is a structural diagram after formation of a gate insulating layer in the fabricating method of the oxide thin film transistor of the first embodiment of the present invention.

FIG. 4 is a structural diagram after formation of an oxide active layer and a protective layer in the fabricating method of the oxide thin film transistor of the first embodiment of the present invention.

FIG. 5 is a structural diagram after formation of source and drain electrodes and annealing in the fabricating method of the oxide thin film transistor of the first embodiment of the present invention.

FIG. 6 is an unannealed transfer current characteristic curve (Ids-Vgs) of the indium gallium zinc oxide (IGZO) thin film transistor in the first embodiment of the present invention.

FIG. 7 is an annealed transfer current characteristic curve (Ids-Vgs) of the indium gallium zinc oxide (IGZO) thin film transistor in the first embodiment of the present invention.

FIG. 8 is a structural diagram of an oxide thin film transistor in a second embodiment of the present invention.

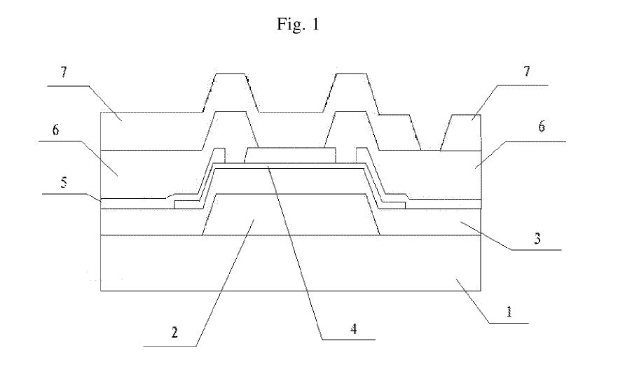

### DESCRIPTION OF THE PREFERRED EMBODIMENT

To make the person skilled in the art better understand the technical solution of the present invention, the present invention is further described below in detail in conjunction with the accompanying drawings and the specific implementations.

### First Embodiment

This embodiment provides a method of fabricating a thin film transistor, comprising following steps of: forming an oxide active layer film and a protective layer film on a substrate, the protective layer film being made of tin oxide-based material, and patterning the oxide active layer film and the protective layer film by one patterning process, to form patterns of an oxide active layer and a protective layer; forming a source and drain electrode film on the protective layer, and patterning the source and drain electrode film by a patterning process, to form patterns of source and drain electrodes; and performing anneal in an oxygen-containing atmosphere, so that the material of the oxide active layer diffuses into the protective layer through a contact surface between the oxide active layer and the protective layer, to form a transitional region in the protective layer, and the material of the protective layer diffuses into the oxide active layer through the contact surface, to form a transitional region in the oxide active layer, the transitional regions being used for reducing an off-state current of the thin film transistor.

In the method of fabricating the thin film transistor of this embodiment, as the protective layer is made of the tin oxide-based material that is insensitive to the etchant for conventional source and drain electrodes, the tin oxide-based protective layer located above the oxide active layer can protect the oxide active layer from influence by the etchant for the source and drain electrodes during fabricating the source and drain electrodes. Compared with the insulating etch stop layer adopted in the prior art, the tin oxide-based protective layer comprises semiconductor material and is electrically matched with the oxide active layer and the source and drain electrodes very well, so there is no need of fabricating via holes in implementation of electric connection between the source and drain electrodes and the oxide active layer, and the protective layer and the oxide active layer may be formed by one patterning process, and compared with the prior art, the patterning process required for individually forming the etch stop layer is omitted and one patterning process is reduced, so that the product has a simple manufacturing procedure, a short manufacturing period, a high yield and a low production cost. In addition, the annealing in the oxygen-containing atmosphere can repair damage of the active layer caused by plasma in deposition of the source and drain electrode film. Moreover, the off-state current of a thin film transistor manufactured without an annealing process in an oxygen-containing atmosphere is very high, and the switching characteristic of the thin film transistor is poor. When the annealing process is performed in the oxygen-containing atmosphere, the material of the oxide active layer and the material of the protective layer diffuse at a contact surface between the oxide active layer and the protective layer, to form transitional regions in respective parts of the oxide active layer and the protective layer in contact with each other, so that the off-state current of the thin film transistor can be reduced.

The protective layer may further comprise a non-transitional region away from the oxide active layer, and the non-transitional region is made of tin oxide-based material. A thickness of the protective layer and a condition of the annealing process are controlled so that a partial region of the protective layer is formed as the structure of the transitional region, that is, a part of the protective layer close to the active layer is the transitional region, and a part of the protective layer away from the active layer is the non-transitional region. The material of the active layer does not diffuse into the non-transitional region of the protective layer, and the non-transitional region of the protective layer is formed of a tin oxide-based material.

Alternatively, the protective layer may be formed of a transitional region, that is to say, in the method of fabricating the thin film transistor of this embodiment, the thickness of the protective layer and the condition of the annealing process may be controlled so that the material of the oxide active layer diffuses into the entire tin oxide-based protective layer, thus completely transforming the protective layer into the transitional region.

The tin oxide-based material may be any of indium tin zinc oxide, aluminum tin zinc oxide, zinc tin oxide, gallium tin oxide, indium gallium tin oxide and indium tin oxide.

The oxide active layer may be made of indium gallium zinc oxide.

In the step of the annealing in the oxygen-containing atmosphere, the oxygen-containing atmosphere is a 1%-99% oxygen partial pressure atmosphere or a pure oxygen atmosphere, and the annealing in the oxygen-containing atmosphere is favorable for repairing damage of the active layer.

In the step of the annealing in the oxygen-containing atmosphere, the annealing is performed at an annealing temperature within the range of 100-900° C. Annealing at the temperature enables the material of the protective layer to diffuse into the oxide active layer through a contact surface between the protective layer and the oxide active layer, to form a transitional region in a part of the oxide active layer in contact with the protective layer, and enables the material of the oxide active layer to diffuse into the protective layer through the contact surface, to form a transitional region in a part of the protective layer in contact with the oxide active layer, so that the off-state current of the thin film transistor can be reduced.

The protective layer may be formed by deposition in an oxygen-containing atmosphere, the oxygen-containing atmosphere being a 1%-99% oxygen partial pressure atmosphere or a pure oxygen atmosphere. The protective layer formed by deposition in the oxygen-containing atmosphere has high oxygen content and is an oxygen-enriched material layer. Annealing in the oxygen-containing atmosphere enables part of oxygen in the oxygen-enriched protective layer to move into the oxide active layer, or oxygen in the active layer to move to be bonded to metal in the oxide active layer, so that the active layer is repaired and properties of the thin film transistor are improved.

Description is given below by taking a method of fabricating a bottom-gate thin film transistor with an oxide active layer of IGZO as an example, and it should be understood that the method is also applicable to a top-gate thin film transistor. The fabricating method comprises the following steps 1 through 4.

In step 1, a metal gate is formed.

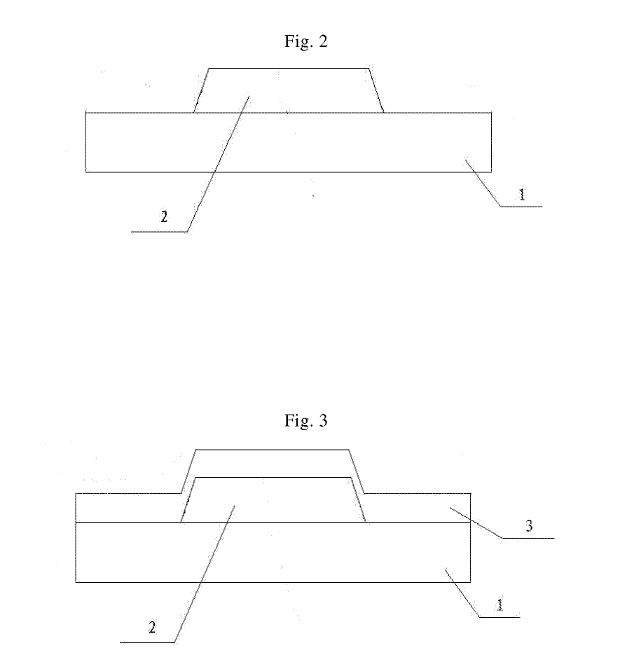

As shown in FIG. 2, firstly a base substrate 1 is cleaned, then a gate metal film is deposited by magnetron sputtering, and a pattern of the gate 2 is formed by a patterning process (including part or all of the processes of photoresist coating, masking, exposure, development, etching, photoresist stripping and the like). The gate 2 and connecting metal may be formed by using metal material or alloy material of Cr, Ti, Mo, W, Al, Cu or the like, and other composite conductive material. The gate metal film described above may be a single-layer or multi-layer structure, with a thickness within the range of 1 nm to 1000 nm. In this embodiment, for example, the thickness of the gate metal film is 700 nm.

In step 2, a gate insulating layer is formed.

As shown in FIG. 3, the gate insulating layer 3 is deposited by chemical vapor deposition (CVD) technology, and a pattern of the gate insulating layer 3 is formed by a patterning process. The gate insulating layer 3 may be formed by using one or more insulating materials of SiOx, SiNx, SiONx, AlOx and the like. In this embodiment, the gate insulating layer 3 is made of SiOx. The gate insulating layer 3 may be a single-layer or multi-layer structure, with a thickness within the range of 1 nm to 500 nm. In this embodiment, for example, the thickness of the gate insulating layer is 300 nm.

In step 3, an active layer and a protective layer are formed.

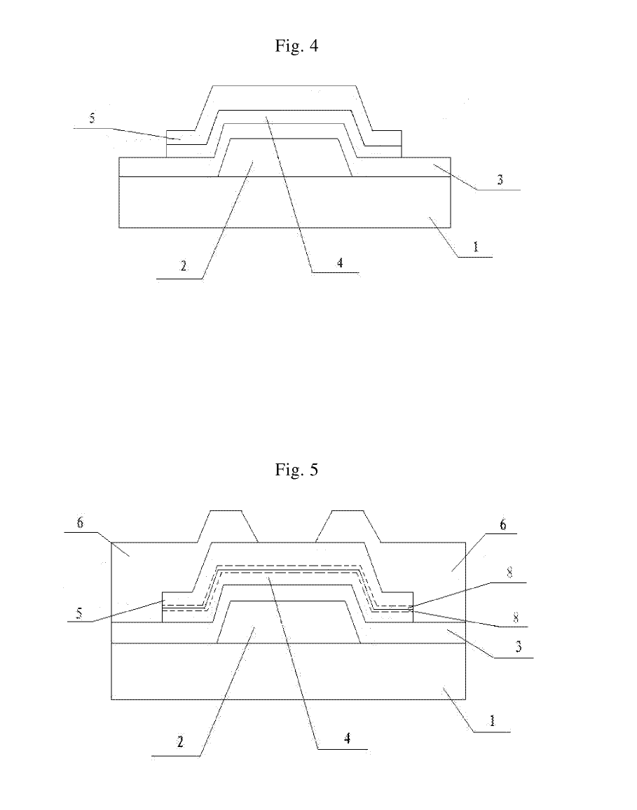

As shown in FIG. 4, firstly the indium gallium zinc oxide (IGZO) active layer 4 is deposited by magnetron sputtering technology, and then the protective layer 5 with a nanoscale thickness is deposited in an oxygen-containing atmosphere which is an atmosphere with an oxygen partial pressure within the range of 1% to 99%. In this embodiment, for example, the oxygen partial pressure is 50%. The protective layer 5 formed by deposition in the oxygen-containing atmosphere has high oxygen content, and thus in a subsequent process of annealing in an oxygen-containing atmosphere, part of oxygen in the oxygen-enriched protective layer 5 can move into the active layer 4, or oxygen within the active layer 4 can move to be bonded to metal within the active layer 4, so that the active layer 4 is repaired and properties of the thin film transistor are improved. The thickness of the protective layer 5 is within the range of 1 nm to 100 nm. In this embodiment, for example, the thickness of the protective layer 5 is 50 nm, and the protective layer 5 may be made of tin oxygen-based material. The tin oxide-based material is insensitive to etching solution for conventional source and drain electrodes, and the tin oxide-based protective layer located above the oxide active layer can protect the oxide active layer from influence by the etching solution for the source and drain electrodes in fabrication of the source and drain electrodes. The tin oxide-based material may be any of indium tin zinc oxide (ITZO), aluminum tin zinc oxide (ATZO), zinc tin oxide (ZTO), gallium tin oxide (GTO), indium gallium tin oxide (IGTO) and indium tin oxide (ITO). In this embodiment, indium tin zinc oxide (ITZO) material is adopted to form the protective layer 5.

A patterning process is performed on the oxide active layer 4 and the protective layer 5, to form a patterned oxide active layer 4 and a patterned protective layer 5, such that the active layer 4 is covered by the protective layer 5, thus avoiding corrosion of the oxide active layer 4 (indium gallium zinc oxide) by the metal etchant during formation of the source and drain electrodes. In addition, during this patterning process, the protective layer can also prevent the etchant from damaging the oxide active layer located below the protective layer.

Compared with the insulating etch stop layer adopted in the prior art, the ITZO protective layer 5 is a semiconductor material layer and is electrically matched with the oxide active layer 4 and the source and drain electrodes very well, so there is no need of fabricating via holes for electric connection between the source and drain electrodes and the oxide active layer 4. Moreover, the protective layer 5 and the oxide active layer 4 may be formed by one patterning process, and compared with the prior art, the photolithography procedure required for individually forming the etch stop layer is omitted, and one patterning process is saved, so that the product has a simple manufacturing procedure, a short manufacturing period, a high yield and a low production cost. The method of fabricating the thin film transistor with the protective layer of IGZO is specifically described in this embodiment, and it should be understood that a thin film transistor including a protective layer formed of other tin oxide-based material also falls within the protection scope of the present invention due to substantially the same fabricating method and technical effects.

In step 4, source and drain electrodes are formed and anneal is performed.

As shown in FIG. 5, a source and drain electrode metal film is deposited by magnetron sputtering technology, and patterns of the source and drain electrodes 6 are formed by a patterning process. The source and drain electrodes 6 and connecting metal may be made of metal material or alloy material of Cr, Ti, Mo, W, Al, Cu or the like, and other composite conductive material. The source and drain electrodes 6 may be a single-layer or multi-layer structure, with a thickness within the range of 1 nm to 1000 nm. In this embodiment, for example, the thickness of the source and drain electrodes 6 is 800 nm. Then, the annealing process is performed in an oxygen-containing atmosphere at an annealing temperature within the range of 100° C. to 900° C., the oxygen-containing atmosphere being an atmosphere with an oxygen partial pressure of 1%-99%. In this embodiment, for example, the annealing temperature is within the range of 300° C. to 500° C., and the oxygen partial pressure is 60%. Annealing process in the oxygen-containing atmosphere enables the oxide active layer to be oxygenated and repaired, thus improving performance of the thin film transistor. Other atmosphere capable of oxygenating and repairing the active layer may also be used in this embodiment and is not limited herein.

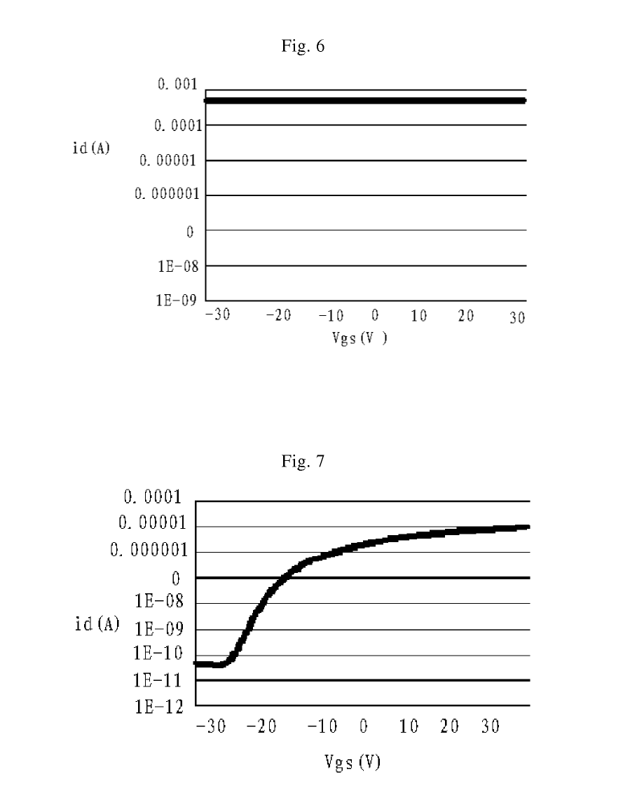

As plasma will damage the oxide active layer 4 in deposition of source and drain electrode metal by magnetron sputtering technology, for example, when the oxide active layer 4 is an indium gallium zinc oxide (IGZO) layer, plasma will damage O—In, O—Ga. and O—Zn bonds in the IGZO material, e.g., the bond rupture causes oxygen diffusion. Annealing in the oxygen-containing atmosphere enables part of oxygen in the oxygen-enriched protective layer 5 to move into the active layer 4, or oxygen within the active layer 4 to move to be bonded to metal within the active layer 4, so that the active layer 4 is repaired and properties of the thin film transistor are improved. Meanwhile, the high temperature in annealing enables substances in the oxide active layer 4 (indium gallium zinc oxide) and the protective layer 5 (such as indium tin zinc oxide) to diffuse into each other to form transitional regions 8 in respective parts of the active layer 4 and protective layer 5 in contact with each other respectively, the transitional regions 8 containing indium gallium tin zinc oxide (InGaZnSnO) material formed due to diffusion. FIG. 6 shows a transfer characteristic curve of a thin film transistor obtained without an annealing process in an oxygen-containing atmosphere. It can be seen from FIG. 6 that the off-state current of the thin film transistor obtained without an annealing process in an oxygen-containing atmosphere is very large, almost in the same order of magnitude as the on-state current, resulting in that the prepared thin film transistor cannot be used normally due to lack of switching characteristic. FIG. 7 shows a transfer characteristic curve of a thin film transistor obtained by annealing in an oxygen-containing atmosphere. It can be seen from FIG. 7 that after subjected to annealing in the oxygen-containing atmosphere, the off-state current of the thin film transistor of this embodiment is obviously reduced as compared with that before annealing (referring to FIG. 6), so the transitional regions formed by annealing in the oxygen-containing atmosphere can reduce the off-state current of the thin film transistor.

It should be understood that the protective layer 5 described above may be entirely formed of a transitional region 8, that is to say, the thickness of the protective layer and the condition of the annealing process may be controlled so that the material of the oxide active layer diffuses into the entire tin oxide-based protective layer, thus completely transforming the protective layer into the transitional region 8. Alternatively, the thickness of the protective layer and the condition of the annealing process may also be controlled so that a partial region of the protective layer 5 is formed as the structure of the transitional region 8, that is, a part of the protective layer close to the active layer 4 is the transitional region 8, and a part of the protective layer away from the active layer 4 is the non-transitional region. In this case, the material of the active layer 4 does not diffuse into the non-transitional region of the protective layer, and the non-transitional region of the protective layer is formed of tin oxide-based material.

In addition, substance diffusion may also occur between the protective layer 5 and the source and drain electrodes 6, so that ohmic contact between the source and drain electrodes and the active layer 4 is improved.

The method of fabricating the thin film transistor is introduced in this embodiment taking the thin film transistor with the oxide active layer of IGZO and the protective layer of ITZO as an example. By applying the fabricating method of this embodiment, when other oxide active layer material (such as zinc oxynitride or the like) and other tin oxide-based protective layer material are adopted, the patterning process can also be reduced, annealing in the oxygen-containing atmosphere can also repair damage of the active layer caused by plasma in deposition of the source and drain electrode film, and transitional regions are formed in respective parts of the oxide active layer and the protective layer in contact with each other respectively, so that the off-state current of the thin film transistor can be reduced. Therefore, methods of fabricating thin film transistors using other oxide active layer material (such as zinc oxynitride or the like) and other tin oxide-based protective layer material also fall within the protection scope of the present invention.

### Second Embodiment

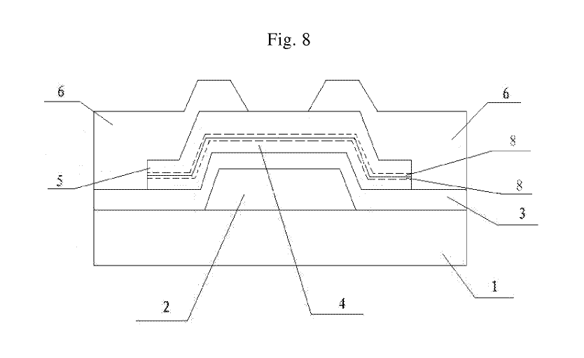

As shown in FIG. 8, this embodiment provides a thin film transistor including an oxide active layer 4, a protective layer 5 located above the oxide active layer 4 and source and drain electrodes 6, the protective layer comprises tin oxide-based material, a part of the oxide active layer 4 in contact with the protective layer 5 includes a transitional region 8, and a part of the protective layer 5 in contact with the oxide active layer 4 includes a transitional region 8, the transitional regions 8 being used for reducing an off-state current of the thin film transistor. For the specific fabricating process of the thin film transistor in this embodiment, reference may be made to the method of the first embodiment, and this is not repeated herein.

Specifically, the protective layer 5 further includes a non-transitional region away from the oxide active layer 4, the transitional region 8 contains material formed by mutual combination of the tin oxide-based material and the material of the oxide active layer through diffusion by annealing, and the non-transitional region is made of tin oxide-based material.

The embodiment is introduced by taking a bottom-gate thin film transistor as an example, and it should be understood that this is also applicable to a top-gate thin film transistor.

The protective layer 5 may be formed of a transitional region 8, that is to say, the entire protective layer 5 is formed of the transitional region 8. The transitional region 8 contains material formed by mutual combination of the tin oxide-based material and the material of the oxide active layer through diffusion by annealing.

One side of the protective layer 5 is in contact with the oxide active layer 4, and the other side of the protective layer 5 is in contact with the source and drain electrodes 6. The oxide active layer 4 is electrically connected with the source and drain electrodes 6 through the protective layer 5, respectively.

The tin oxide-based material may be any of indium tin zinc oxide (ITZO), aluminum tin zinc oxide (ATZO), zinc tin oxide (ZTO), gallium tin oxide (GTO), indium gallium tin oxide (IGTO) and indium tin oxide (ITO).

The oxide active layer 4 may be made of indium gallium zinc oxide (IGZO).

It should be understood that semiconductor of other element or compound semiconductor may be used for fabricating the active layer, and other amorphous, polycrystalline, monocrystalline and hybrid semiconductors may also be used for fabricating the active layer.

The thickness of the protective layer 5 is within the range of 1 nm to 100 nm.

The thickness of the active layer 4 is within the range of 5 nm to 200 nm.

When the oxide active layer is made of IGZO, the tin oxide-based material and the material of the oxide active layer 4 are annealed to form transitional region material layers containing indium gallium tin zinc oxide, and the formed transitional regions can reduce the off-state current of the thin film transistor.

The transitional regions 8 of the thin film transistor in this embodiment are formed by mutual combination of the material of the protective layer 5 and the material of the oxide active layer 4 through diffusion by annealing, and compared with the thin film transistor obtained without an annealing process in an oxygen-containing atmosphere, the thin film transistor in this embodiment has a lower off-state current and excellent properties.

Furthermore, as the protective layer 5 is made of the tin oxide-based material which has good barrier effect on etchant for the source and drain, providing of the protective layer can ensure that the performance of the oxide active layer 4 is not affected by the etchant for the source and drain during fabrication of the thin film transistor, and as the protective layer 5 made of the tin oxide-based material can also prevent influence on the oxide active layer 4 in subsequent fabrication of functional layers, for example, influence on the oxide active layer 4 in film formation of the source and drain electrodes 6 by sputtering, in addition to protecting the oxide active layer 4 from corrosion by the etchant for the source and drain.

Furthermore, the etch stop layer 5 in the prior art is generally made of insulting material, and thus via holes are required to be formed in the etch stop layer 5, and the active layer 4 is electrically connected with the source and drain electrodes 6 through the via holes, thus requiring a separate patterning process for fabricating the etch stop layer 5. The protective layer 5 in this embodiment is made of tin oxide-based material and has semiconductor properties, so there is no need of forming via holes in the protective layer 5, and the protective layer 5 and the oxide active layer 4 may be patterned by one patterning process, thus reducing one patterning process, simplifying the manufacturing procedure of the thin film transistor, shortening the manufacturing period of the thin film transistor, while improving the yield and reducing the production cost. Therefore, the thin film transistor in this embodiment has a simple manufacturing procedure, a high yield and a low production cost.

### Third Embodiment

This embodiment provides a display substrate including the thin film transistor described above and other necessary functional layers and connecting wires known to the person skilled in the art.

The display substrate provided by this embodiment has a simple manufacturing procedure, a high yield and a low production cost.

### Fourth Embodiment

This embodiment provides a display device including the display substrate described above. The display device provided by this embodiment has a simple manufacturing procedure, a high yield and a low production cost.

It should be understood that the display device may be applied to LCD TVs, high-definition digital TVs, (desktop and laptop) computers, mobile phones, PDAs, GPSs, vehicle displays, projection displays, video cameras, digital cameras, electronic watches, calculators, electronic instruments, meters, public displays, virtual displays and the like.

It should be understood that the above implementations are only exemplary implementations for illustrating the principle of the present invention; however, the present invention is not limited thereto. Various variations and improvements can be made by the person of ordinary skill in the art without departing from the spirit and essence of the present invention, and these variations and improvements should also be considered to be within the protection scope of the present invention.

1-20. (canceled)

21. A fabricating method of a thin film transistor, comprising steps of:
forming an oxide active layer film and a protective layer film on a substrate, and patterning the oxide active layer film and the protective layer film by one patterning process, to form patterns of an oxide active layer and a protective layer, the protective layer film being made of tin oxide-based material;
forming a source and drain electrode film on the protective layer, and patterning the source and drain electrode film by a patterning process, to form patterns of source and drain electrodes; and
annealing in an oxygen-containing atmosphere, so that the material of the oxide active layer diffuses into the protective layer through a contact surface between the oxide active layer and the protective layer, to form a transitional region in the protective layer, and the material of the protective layer diffuses into the oxide active layer through the contact surface, to form a transitional region in the oxide active layer, the transitional regions being configured to reduce an off-state current of the thin film transistor.

22. The fabricating method of the thin film transistor of claim 21, wherein the protective layer further comprises a non-transitional region away from the oxide active layer, and the non-transitional region is made of the tin oxide-based material.

23. The fabricating method of the thin film transistor of claim 21, wherein the protective layer is formed of the transitional region.

24. The fabricating method of the thin film transistor of claim 21, wherein the tin oxide-based material is any one of indium tin zinc oxide, aluminum tin zinc oxide, zinc tin oxide, gallium tin oxide, indium gallium tin oxide and indium tin oxide.

25. The fabricating method of the thin film transistor of claim 24, wherein the oxide active layer is made of indium gallium zinc oxide.

26. The fabricating method of the thin film transistor of claim 25, wherein the transitional region comprises indium gallium tin zinc oxide material.

27. The fabricating method of the thin film transistor of claim 21, wherein the oxygen-containing atmosphere in the step of annealing in the oxygen-containing atmosphere is 1%-99% oxygen partial pressure atmosphere or pure oxygen atmosphere.

28. The fabricating method of the thin film transistor of claim 21, wherein the annealing in the step of annealing in the oxygen-containing atmosphere is performed at an annealing temperature within the range of 100° C. to 900° C.

29. The fabricating method of the thin film transistor of claim 21, wherein the protective layer is formed by deposition in an oxygen-containing atmosphere, the oxygen-containing atmosphere is 1%-99% oxygen partial pressure atmosphere or pure oxygen atmosphere.

30. A thin film transistor, comprising an oxide active layer, a protective layer provided on the oxide active layer and source and drain electrodes, wherein the protective layer comprises tin oxide-based material, a part of the oxide active layer in contact with the protective layer comprises a transitional region, and a part of the protective layer in contact with the oxide active layer comprises a transitional region, the transitional regions are configured to reduce an off-state current of the thin film transistor.

31. The thin film transistor of claim 30, wherein the protective layer further comprises a non-transitional region away from the oxide active layer,
the transitional region contains material formed by mutual combination of the tin oxide-based material and the material of the oxide active layer, the non-transitional region is made of the tin oxide-based material.

32. The thin film transistor of claim 30, wherein the protective layer is formed of the transitional region, and the transitional region contains material formed by mutual combination of the tin oxide-based material and the material of the oxide active layer.

33. The thin film transistor of claim 30, wherein one side of the protective layer is in contact with the oxide active layer, the other side of the protective layer is in contact with the source and drain electrodes, and the oxide active layer is electrically connected with the source and drain electrodes through the protective layer, respectively.

34. The thin film transistor of claim 31, wherein the tin oxide-based material is any one of indium tin zinc oxide, aluminum tin zinc oxide, zinc tin oxide, gallium tin oxide, indium gallium tin oxide and indium tin oxide.

35. The thin film transistor of claim 34, wherein the oxide active layer is made of indium gallium zinc oxide.

36. The thin film transistor of claim 35, wherein the protective layer has a thickness within a range of 1 nm to 100 nm.

37. The thin film transistor of claim 36, wherein the oxide active layer has a thickness within a range of 5 nm to 200 nm.

38. The thin film transistor of claim 35, wherein the transitional region formed by mutual combination of the tin oxide-based material and the material of the oxide active layer comprises indium gallium tin zinc oxide material.

39. A display device, comprising a display substrate, the display substrate comprising thin film transistors, the thin film transistor comprising an oxide active layer, a protective layer provided on the oxide active layer and source and drain electrodes, wherein
the protective layer comprises tin oxide-based material, a part of the oxide active layer in contact with the protective layer comprises a transitional region, and a part of the protective layer in contact with the oxide active layer comprises a transitional region, the transitional regions are configured to reduce an off-state current of the thin film transistor.

40. The display device of claim 39, wherein the transitional regions comprise material formed by mutual combination of the tin oxide-based material and the material of the oxide active layer.
